(19) United States
(12) Patent Application Publication
(10) Pub. No.: US 2026/0194313 A1
(43) Pub. Date: Jul. 9, 2026

(54) FIN ARCHITECTURE FOR PROMOTING HEAT TRANSFER FLUID STIRRING

(71) Applicant: THALES, MEUDON (FR)

(72) Inventor: Ivan GRIMARDIAS, Sophia Antipolis (FR)

(21) Appl. No.: 19/134,733

(22) PCT Filed: Dec. 11, 2023
(86) PCT No.: PCT/EP2023/085034

§ 371 Date: Jun. 1, 2025

(30) Foreign Application Priority Data
Dec. 27, 2022 (FR) FR2214519

(51) Int. Cl. F28F 13/12; F28D 21/00

(52) U.S. Cl. CPC F28F 13/125; F28D 2021/0029

(57) ABSTRACT

A cooling device is provided having a heat exchange surface to allow an exchange of heat with a heat transfer fluid along the heat exchange surface in a first direction, the exchange of heat being brought about by convection between the heat exchange surface and the heat transfer fluid, the cooling device including at least one cooling fin, the heat exchange surface receiving, by conduction, heat that is to be discharged by the cooling fin, the cooling fin including at least one fixed fluid-swirling guide spaced apart from the heat exchange surface, the at least one fluid-swirling guide having a warped surface, the at least one fluid-swirling guide being disposed so that the heat transfer fluid is redirected in a second direction intersecting the first direction.

### CROSS-REFERENCE TO RELATED APPLICATIONS

This application is a National Stage of International patent application PCT/EP2023/085034, filed on Dec. 11, 2023, which claims priority to foreign French patent application No. FR 2214519, filed on Dec. 27, 2022, the disclosures of which are incorporated by reference in their entireties.

### FIELD OF THE INVENTION

The invention relates to the cooling of a heat-generating element. The invention is applicable in the field of electric machines and power electronics. Indeed, it is known that electronic devices, computers, and electronics in general give rise to losses that manifest themselves in the generation of heat, which must be discharged. It therefore becomes a priority to discharge this heat, ensuring that the elements cited above can operate correctly. The invention is particularly applicable in the field of on-board electronics, where the tendency is to increase the number of electric devices and thus the on-board electrical power.

The invention relates more particularly to an architecture of a cooling fin for such a heat exchanger.

### BACKGROUND

Currently, a lot of electronic systems are equipped with a heat exchanger for discharging heat from elements that give off heat energy towards a source for discharging that heat, in order to allow these electronics to operate in optimum conditions.

Known at present are heat exchangers comprising a set of fins disposed in an axis of movement of a heat transfer fluid for which an exchange of heat with a second fluid or the very thermal element is desired, for example straight fins in the direction of an air stream traversing the heat exchanger acting as fins for extracting the heat energy and transmitting it to a lower-temperature fluid, or a fluid utilizing the fins to extract the heat energy generated by an electronic component.

The function of the fins is to allow an exchange of heat between two fluids, or a fluid and a solid heat-conducting element, these two elements being at different temperatures. More specifically, the fins are thus interfaces serving to improve the effectiveness of exchanges between the cited elements, i.e. the two heat transfer fluids or the fluid and the solid element.

However, the use of a single heat transfer stream which sweeps over the heat exchanger is preferred for compactness and weight reasons. Specifically, adding a second heat transfer fluid and the entire circuit for the circulation of this second fluid often creates excess mass and volume that then need to be taken into consideration, especially in the field of aeronautics in which the main problems concern managing the mass of the vehicle.

As a result, at present the cooling of an electric machine is limited by mass and bulk constraints and the prior art is not capable of overcoming this.

Thus, in a configuration for cooling between a heat transfer fluid directly extracting heat from the fins of the heat exchanger, an exchange surface in contact with the heat exchanger and with the heat transfer fluid, at the cooling fins, can be identified for allowing this heat extraction.

However, this direct extraction of the heat depends on the difference in temperature between the temperature of the heat exchange surface of the heat exchanger, or generally of the cooling fin, and the temperature of the heat transfer fluid sweeping over this heat exchange surface and the cooling device. Specifically, the greater the difference in temperature between the heat exchange surface and the heat transfer fluid is, the more heat is exchanged. Thus, a heat exchange surface with a high temperature relative to the temperature of the heat transfer fluid, or, conversely, a low temperature of the heat transfer fluid relative to the temperature of the heat exchange surface makes it possible to considerably improve the exchange of heat.

However, the temperature of the heat transfer fluid varies as the heat transfer fluid sweeps over the heat exchange surface and the cooling fins of the cooling device. Specifically, the exchange of heat that occurs between the heat exchange surface and the heat transfer fluid causes an increase in the temperature of the heat transfer fluid which exchanges heat along the exchange surface of the cooling device. This increase in the temperature of the heat transfer fluid and thus this reduction in the temperature difference between the hot body, i.e. the heat exchange surface, and the cold body, i.e. the heat transfer fluid, adversely affects the extraction of heat between these two bodies.

### SUMMARY OF THE INVENTION

The invention aims to overcome all or some of the problems cited above by providing a cooling fin architecture which makes it possible both to swirl the heat transfer fluid sweeping over the fin, allowing the temperature of the heat transfer fluid exchanging heat with the heat exchange surface to even out, and to discharge the heat transfer fluid at a high temperature and replace it with heat transfer fluid at a lower temperature, thus improving the extraction of heat.

The invention advantageously makes it possible to increase the duration of exchange between a hot body and the heat transfer stream by lengthening the distance traveled by the heat transfer fluid along the hot body.

To that end, the invention relates to a cooling device having a heat exchange surface configured to allow an exchange of heat with a heat transfer fluid along the heat exchange surface in a first direction, the exchange of heat being brought about by convection between the heat exchange surface and the heat transfer fluid, the cooling device comprising at least one cooling fin, the heat exchange surface being configured to receive, by conduction, heat that is to be discharged by the cooling fin, the cooling fin comprising at least one fixed fluid-swirling guide spaced apart from the heat exchange surface, the at least one fluid-swirling guide having a warped surface, the at least one fluid-swirling guide being disposed so that the heat transfer fluid is redirected in a second direction intersecting the first direction.

According to one aspect of the invention, the second direction is oriented toward the heat exchange surface, the second direction having a component substantially perpendicular to the heat exchange surface.

According to one aspect of the invention, the at least one swirling guide is disposed so that the heat transfer fluid is redirected in a third direction intersecting the first direction and the second direction, the third direction having the same origin as the second direction in a first plane perpendicular to the heat exchange surface, the third direction having a component substantially perpendicular to the heat exchange surface that opposes the component substantially perpendicular to the heat exchange surface of the second direction in the first plane.

According to one aspect of the invention, the cooling fin comprises:
a first wall extending in a second plane substantially parallel to the first direction and parallel to the first plane, the first wall being configured to receive, by conduction, heat that is to be discharged by the cooling fin, the at least one swirling guide being connected to the first wall via a first fixing support.

According to one aspect of the invention, the cooling fin comprises:
a second wall extending in a third plane parallel to the first plane and separate from the second plane, the swirling guide being connected to the second wall via a second fixing support.

According to one aspect of the invention, the second plane is parallel to the first plane and/or the third plane is parallel to the first plane.

According to one aspect of the invention, the heat transfer fluid present between the first wall and the second wall comprises a first volume of heat transfer fluid disposed between the heat exchange surface and a first guide surface of the at least one swirling guide for swirling the heat transfer fluid and a second volume of heat transfer fluid in contact with a second guide surface of the at least one fluid-swirling guide, the first guide surface having a concave shape and the second guide surface having a concave shape with respect to a first segment substantially coinciding with the at least one fluid-swirling guide and parallel to the first direction.

According to one aspect of the invention, the at least one fluid-swirling guide comprises an inversion interface for inverting the heat transfer fluid and configured to redirect the heat transfer fluid present in the second volume of heat transfer fluid toward the first volume of heat transfer fluid.

According to one aspect of the invention, the inversion interface for inverting the heat transfer fluid is configured to redirect the heat transfer fluid present in the first volume of heat transfer fluid toward the second volume of heat transfer fluid.

According to one aspect of the invention, the inversion interface for inverting the heat transfer fluid comprises a first stream inversion zone connected to the first wall and/or the second wall and a second stream inversion zone connected to the first wall and/or the second wall, the first guide surface in the first inversion zone having a concave shape with respect to the heat exchange zone and the second guide surface in the second inversion zone having a convex shape with respect to the heat exchange surface.

According to one aspect of the invention, the first guide surface in the first inversion zone has a concave shape between two boundaries of the first segment and the second guide surface in the second inversion zone has a concave shape between the two boundaries of the first segment.

According to one aspect of the invention, the first inversion zone is capable of inducing a first rotation of the heat transfer fluid of the first volume of heat transfer fluid and wherein the second inversion zone is capable of inducing a second rotation of the heat transfer fluid of the second volume of heat transfer fluid about an axis of rotation parallel to the first direction.

According to one aspect of the invention, the at least one swirling guide comprises an additional guide extending perpendicularly in relation to the first wall and to the second wall, the additional guide comprising a first additional guide surface facing the first wall and a second additional guide surface facing the second wall, the first additional guide surface and the second additional guide surface having a convex shape along a second segment substantially coinciding with the additional guide and parallel to the first direction.

According to one aspect of the invention, the first guide surface in the first inversion zone and the second guide surface in the second inversion zone are defined according to the following mathematical equation:

$$D = {f}_{1} ( X ) \cdot sin ( {f}_{2} ( X ) )$$

where D represents the movement of the heat transfer fluid with respect to the first direction between an entrance of the inversion interface and an exit of the inversion interface in the first direction, X represents a position of the heat transfer fluid along the first direction between the entrance of the inversion interface and the exit of the inversion interface, X being arbitrarily defined as 0 at the entrance to the inversion interface, and fₓ represent any mathematical functions.

According to one aspect of the invention, the first guide surface in the first inversion zone and the second guide surface in the second inversion zone are defined according to the following mathematical equation:

$$D = {\sum }_{0}^{n} {α}_{n} \cdot {X}^{n}$$

where D represents the movement of the heat transfer fluid with respect to the first direction between an entrance of the inversion interface and an exit of the inversion interface in the first direction, X represents a position of the heat transfer fluid along the first direction between the entrance of the inversion interface and the exit of the inversion interface, X being arbitrarily defined as 0 at the entrance to the inversion interface, and αₙ represents a parameter of the real coefficient type.

### BRIEF DESCRIPTION OF THE DRAWINGS

The invention will be better understood and further advantages will become apparent upon reading the detailed description of one embodiment given by way of example, the description being illustrated by the appended drawing in which:

FIG. 1 shows a schematic view of a swirling guide and a heat exchange surface of a cooling fin according to the invention;

FIG. 2 shows a schematic view of a preferential configuration of a cooling fin comprising the swirling guide;

FIG. 3 shows a top view of the swirling guide of the cooling fin from FIG. 2;

FIG. 4 shows a stream inversion interface according to the invention;

FIG. 5 shows a top view of the stream inversion interface from FIG. 4;

FIG. 6 shows a schematic view of a first configuration for the positioning of the swirling guide according to the invention;

FIG. 7 shows a schematic view of a second configuration for the positioning of the swirling guide according to the invention;

FIG. 8 shows a schematic view of a third configuration for the positioning of the swirling guide according to the invention;

FIG. 9 shows a schematic view of a fourth configuration for the positioning of the swirling guide according to the invention;

FIG. 10 shows a schematic view of a fifth configuration for the positioning of the swirling guide according to the invention;

FIG. 11 shows a schematic view of the stream inversion interface establishing a rotation of the stream;

FIG. 12 is a spatial representation of the movement of two heat transfer fluids traversing the cooling fin according to a first model;

FIG. 13 is a spatial representation of the movement of two heat transfer fluids traversing the cooling fin according to a second model;

FIG. 14 is a spatial representation of the movement of two heat transfer fluids traversing the cooling fin according to a third model;

FIG. 15 is a spatial representation of the movement of two heat transfer fluids traversing the cooling fin according to a fourth model.

For the sake of clarity, the same elements will bear the same reference signs in the various figures.

### DETAILED DESCRIPTION

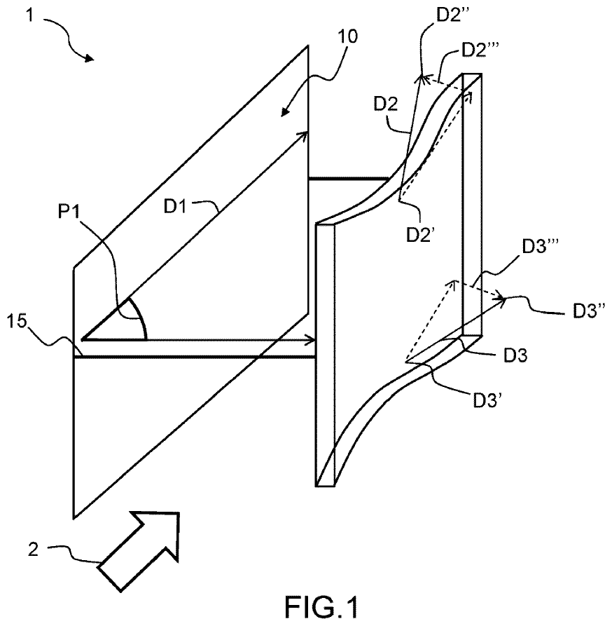

FIG. 1 shows an enlarged schematic view of a cooling fin 12 of a cooling device 1. The cooling device 1 thus comprises a multitude of cooling fins 12. A heat transfer fluid 2 sweeps over each cooling fin 12 in a first direction D1. The cooling device has a heat exchange surface 10 which is also the base of the cooling fin 12. The cooling device 1 is thus configured to allow an exchange of heat with the heat transfer fluid 2 along the heat exchange surface 10 in the first direction D1, the exchange of heat occurring by convection between the heat exchange surface 10 and the heat transfer fluid 2. In addition, the heat exchange surface 10 is also configured to receive, by conduction, heat that is to be discharged by the cooling fin 12. In other words, the heat exchange surface 10 is intended to receive heat from a hot source by conduction. The heat exchange surface 10 advantageously comprises a thermally conductive material. This heat is also transmitted from the heat exchange surface 10 to the heat transfer fluid 2 that traverses the cooling fin 12 by convection so that the heat is discharged from the cooling device 1, this exchange of heat happening mainly along the heat exchange surface 10 and in the vicinity of the heat exchange surface 10.

However, the transfer of heat from the heat exchange surface 10 to the heat transfer fluid 2 locally increases the temperature of the heat transfer fluid 2 in the vicinity of the heat exchange surface 10. Also, since the exchange of heat is efficient when the two heat-exchanging bodies are at very different temperatures, the increase in the temperature of the heat transfer fluid 2 locally and in the vicinity of the heat exchange surface 10 adversely affects the efficiency of this extraction of heat all through the cooling fin 12 over which the heat transfer fluid 2 sweeps.

Thus, advantageously, the cooling fin 12 comprises at least one fluid-swirling guide 14 which is fixed in relation to the heat exchange surface 10. In other words, the at least one swirling guide 14 is secured and fitted in relation to the heat exchange surface 10. The at least one swirling guide 14 is also spaced apart from the heat exchange surface 10. The cooling fin 12 can thus comprise a multitude of swirling guides 14 disposed randomly in the cooling fin 12, or aligned mutually parallel with respect to the first direction D1 or aligned with one another in any direction.

The at least one fluid-swirling guide 14 also has a warped surface. In other words, the at least one fluid-swirling guide 14 has a non-developable ruled surface, i.e. a surface created by the movement of a straight line, two successive positions of which are generally not in the same plane. Thus, the warped surface of the fluid-swirling guide 14 does not satisfy a development rule.

As a result, via this warped surface, the at least one fluid-swirling guide 14 is disposed so that the heat transfer fluid 2 is redirected in a second direction D2 intersecting the first direction D1.

The at least one fluid-swirling guide 14 thus makes it possible to redirect some of the heat transfer fluid 2 traversing the cooling fin 12 so as to generate a swirl in the heat transfer fluid 2 between a hot heat transfer fluid 2′ in the vicinity of the heat exchange surface 10 and a heat transfer fluid 2″ colder than the heat transfer fluid 2′. This mixture of fluid then makes it possible to even out the overall temperature of the heat transfer fluid 2 and thus to cool the heat transfer fluid 2′ located in the vicinity of the heat exchange surface 10 and to improve the exchange of heat between the heat exchange surface 10, or the hot body, and the heat transfer fluid 2′ located in the vicinity of the heat exchange surface 10.

The fluid-swirling guide 14 also makes it possible to generate local turbulence that improves the exchange of heat.

As mentioned above, the fluid-swirling guide 14 is secured to the heat exchange surface 10. Thus, it is conceivable to secure the fluid-swirling guide 14 to the heat exchange surface 10 via a fixing finger 15 or via multiple fixing fingers 15 as shown in FIG. 1.

In addition, as shown in FIG. 1, the second direction D2 is oriented toward the heat exchange surface 10. Specifically, the second direction D2 can be defined by an origin D2′ and an end D2″. Also, the end D2″ of the second direction D2 is at a smaller distance than the origin D2′ of the second direction D2 is. In other words, the second direction D2 comprises a component D2″ substantially perpendicular to the heat exchange surface 10.

Therefore, the at least one fluid-swirling guide 14 makes it possible to deflect the heat transfer fluid 2 in the vicinity of the heat exchange surface such that an oscillation is generated in the flow of the heat transfer fluid 2 along the heat exchange surface 10. This oscillation in the flow of the heat transfer fluid 2 along the heat exchange surface 10 has the advantage of lengthening the distance traveled by the heat transfer fluid 2 along the heat exchange surface 10 and thus of prolonging the time during which heat can be exchanged between the heat transfer fluid 2 and the heat exchange surface 10, improving the extraction of heat. Moreover, the at least one fluid-swirling guide 14 also has the advantage of not impacting the velocity of the heat transfer fluid 2. Specifically, an acceleration of the heat transfer fluid 2 along the exchange surface shortens the time in which heat can be exchanged and limits the extraction of heat, whereas slowing down the velocity of the heat transfer fluid in the cooling fin 12 greatly limits the convection effect occurring between the heat exchange surface 10 and the low-velocity heat transfer fluid 2. Thus, the at least one swirling guide 14 has the advantage of lengthening the distance traveled by the heat transfer fluid in the vicinity of the heat exchange surface 10 without impacting the capacity for heat extraction of the heat transfer fluid 2.

In addition, the at least one fluid-swirling guide 14 has the advantage of creating areas of overpressure and areas of negative pressure, promoting the movement of the heat transfer fluid 2 with respect to the heat exchange surface 10 in the cooling fin 12.

Moreover, the at least one swirling guide 14 is disposed so that the heat transfer fluid 2 is redirected in a third direction D3 intersecting the first direction D1 and the second direction D2. The third direction D3 also comprises an origin D3′ and an end D3″. Also, the origin D3′ of the third direction D3 is superimposed with the origin D2′ of the second direction D2 in a first plane P1 parallel to the first direction D1 and perpendicular to the heat exchange surface 10. In other words, in the first plane P1, the second direction D2 and the third direction D3 have the same origin, i.e. the origin D2′ of the second direction D2 and the origin D3′ of the third direction coincide.

Also, similarly to the second direction D2, the third direction D3 has a component D3′″ substantially perpendicular to the heat exchange surface 10 and opposed to the component D2′″ substantially perpendicular to the heat exchange surface 10 of the second direction D2 in the first plane P1. In other words, the origin D3′ of the third direction D3 is at a smaller distance than the end D3″ of the third direction D3″ is, and therefore the third direction D3 is oriented such that it does not point toward the heat exchange surface 10.

As a result, the at least one fluid-swirling guide 14 has the advantage of allowing the heat transfer fluid 2 to be redirected in two intersecting, or even opposite directions, via the second direction D2 and the third direction D3, simultaneously for the heat transfer fluid 2 in contact with the at least one fluid-swirling guide 14. More specifically, the at least one fluid-swirling guide 14 is capable of redirecting the hot heat transfer fluid 2′ which is in the vicinity of the heat exchange surface 10 in the third direction D3 such that the hot heat transfer fluid 2′ moves away from the heat exchange surface 10 and of redirecting the cold heat transfer fluid 2″ at a distance from the heat exchange surface 10 in the second direction D2 so that it moves closer to the heat exchange surface 10, these two redirections happening simultaneously, i.e. for a fluid coming into contact with the at least one fluid-swirling guide 14, the redirection in the second direction D2 and in the third direction D3 does not happen in succession but at the same time.

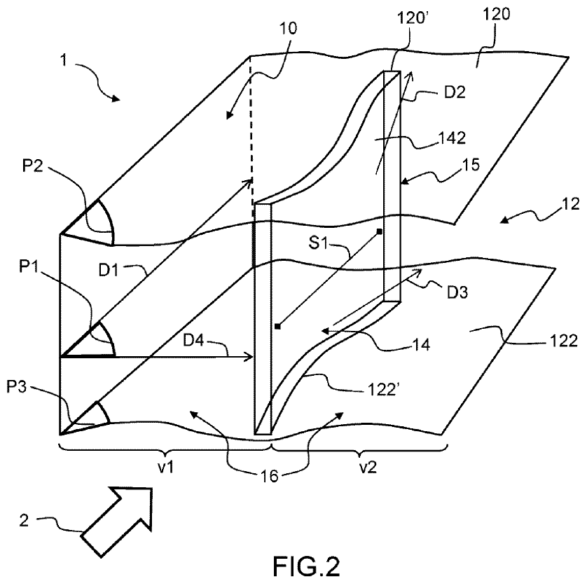

According to a configuration shown in FIG. 2, the cooling fin 12 may also comprise a first wall 120 extending in a second plane P2 substantially parallel to the first direction D1 and to the first plane P1. The first wall 120 is configured to receive, by conduction, heat from the heat exchange surface 10 that is to be discharged by the cooling fin 12. Moreover, the first wall 120 comprises a thermally conductive material.

The at least one fluid-swirling guide 14 is connected to the first wall 120 via a first fixing support 120′. The first wall 120 also becomes thermally conductive so that the heat to be discharged is distributed over a larger surface area, i.e. the heat exchange surface 10 and the first wall 120, while at the same time the securing of the at least one swirling guide 14 with respect to the heat exchange surface 10 is improved.

It is also conceivable for the cooling fin 12 to comprise a second wall 122 extending in a third plane P3 substantially parallel to the first direction D1 and to the first plane P1. The third plane P3 is separate from and parallel to the second plane P2. The second wall 122 is configured to receive, by conduction, heat from the heat exchange surface 10 that is to be discharged by the cooling fin 12. Moreover, the second wall 122 comprises a thermally conductive material.

The at least one fluid-swirling guide 14 is connected to the second wall 122 via a second fixing support 122′. The second wall 122 also becomes thermally conductive so that the heat to be discharged is distributed over a larger surface area, i.e. the heat exchange surface 10, the first wall 120 and the second wall 122, while at the same time the securing of the at least one swirling guide 14 with respect to the heat exchange surface 10 is improved.

The first wall 120 and the second wall 122 thus form a cavity 16 into which the heat transfer fluid 2 is introduced and into which the at least one fluid-swirling guide 14 is developed.

In a variant, it is also conceivable for the first wall 120 or the second wall 122 not to extend perpendicularly in relation to the heat exchange surface 10. More specifically, it is conceivable for the second plane P2 and/or the third plane P3 to extend in a plane which intersects the first plane P1 so that a cooling fin 12 with a triangular shape or the shape of an inverted triangle is produced.

The heat transfer fluid 2 is thus contained between the first wall 120 and the second wall 122 and, more specifically, may be contained in a first volume v1 of heat transfer fluid disposed between the heat exchange surface 10 and a first guide surface 140 of the at least one swirling guide 14 for swirling the heat transfer fluid and a second volume v2 of heat transfer fluid in contact with a second guide surface 142 of the at least one fluid-swirling guide 14. The first guide surface 140 of the at least one fluid-swirling guide 14 faces the heat exchange surface 10, whereas the second guide surface 142 of the at least one fluid-swirling guide 14 is opposite to the first guide surface 140 in a fourth direction D4 perpendicular to the first direction D1 and parallel to the first plane P1. The cavity 16 is thus composed of the first volume v1 and the second volume v2. The first volume v1 thus represents a volume of hot heat transfer fluid 2′ in the vicinity of the heat exchange surface 10 whereas the volume v2 represents a volume of cold heat transfer fluid 2″ further away from the heat exchange surface 10 than the heat transfer fluid 2′ is.

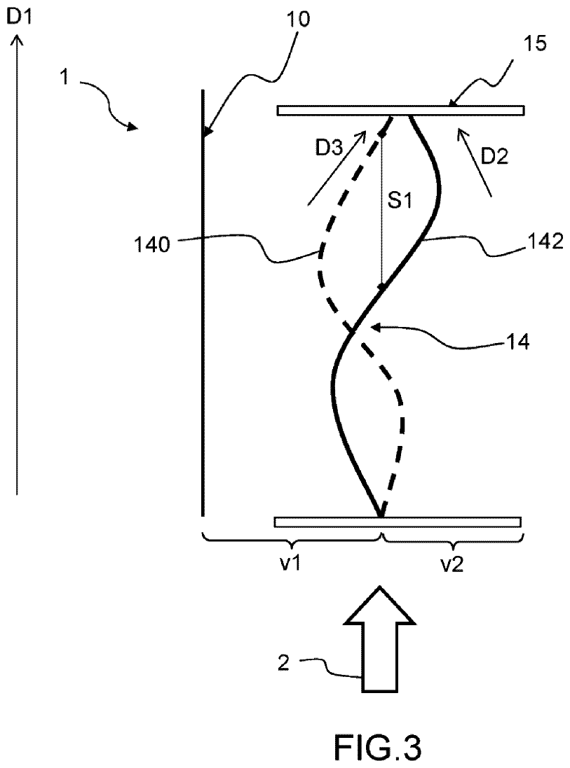

As shown in FIG. 3, the first guide surface 140 has a concave shape with respect to a first segment S1 substantially coinciding with the at least one fluid-swirling guide 14, parallel to the first direction D1 and comprised in the first plane P1. The second guide surface 142 also has a concave shape with respect to the first segment S1. Thus, with respect to the heat exchange surface 10, the first guide surface 140 has a convex shape whereas the second guide surface 142 has a concave shape. As a result, the concave shape of the first guide surface 140 makes it possible to orient the hot heat transfer fluid 2′ of the first volume v1 toward the third direction D3 while the concave shape of the second guide surface 142 makes it possible to orient the cold heat transfer fluid 2″ of the second volume v2 toward the second direction D2.

In a variant, it is also conceivable for the first guide surface 140 and the second guide surface 142 to have a substantially planar shape, the planar shape of the first guide surface 140 being parallel to the third direction D3 and the planar shape of the second guide surface 142 being parallel to the second direction D2.

Thus, the non-ruled warped surface of the fluid-swirling guide 14 allows the latter to redirect the heat transfer fluid 2 in at least two directions, i.e. the second direction D2 and the third direction D3, and thus to swirl the hot heat transfer fluid 2′ with the cold heat transfer fluid 2″ such that the local temperature of the heat transfer fluid 2 in the vicinity of the heat exchange surface 10 is reduced.

More specifically, the fluid-swirling guide 14 comprises an inversion interface 15 for inverting the heat transfer fluid and configured to redirect the cold heat transfer fluid 2″ present in the second volume v2 of heat transfer fluid toward the first volume v1 of heat transfer fluid. The inversion interface 15 makes it possible to invert the position of the heat transfer fluid 2 traversing the cooling fin 12. Specifically, the inversion interface 15 makes it possible to simultaneously move the cold heat transfer fluid 2″ from the second volume v2 into the first volume v1. In other words, the fluid inversion interface 15 makes it possible to move the cold heat transfer fluid 2″ at a distance from the heat exchange surface 10 and present in the second volume v2 into the first volume v1 and thus to move the cold heat transfer fluid 2″ closer to the heat exchange surface 10. Specifically, at the fluid inversion interface 15, the concave shape of the second guide surface 142 makes it possible to orient the cold heat transfer fluid 2″ in the direction of the second direction D2 which is oriented toward the heat exchange surface 10 and thus toward the first volume v1.

Moreover, the inversion interface 15 for inverting the heat transfer fluid may also be configured to redirect the hot heat transfer fluid 2′ present in the first volume v1 of heat transfer fluid toward the second volume v2 of heat transfer fluid. However, as mentioned above, the inversion interface 15 makes it possible to simultaneously move the hot heat transfer fluid 2′ from the first volume v1 into the second volume v2. In other words, the fluid inversion interface 15 makes it possible to move the hot heat transfer fluid 2′ in the vicinity of the heat exchange surface 10 and present in the first volume v1 into the second volume v2 and thus to move the hot heat transfer fluid 2′ away from the heat exchange surface 10. Specifically, at the fluid inversion interface 15, the concave shape of the first guide surface 140 makes it possible to orient the hot heat transfer fluid 2′ in the direction of the third direction D3 which is oriented substantially away from the heat exchange surface 10 and thus toward the second volume v2.

As a result, the inversion interface 15 makes it possible to simultaneously move two volumes that are superimposed with respect to the heat exchange surface 10, i.e. the first volume v1 and the second volume v2, and to invert the position of the two volumes with respect to the heat exchange surface 10 such that the volume of heat transfer fluid furthest away from the exchange surface, i.e. the second volume v2 in the configuration shown in FIG. 3, is in the vicinity of the heat exchange surface 10 and that the volume closest to the heat exchange surface 10, i.e. the first volume, which is initially present between the heat exchange surface 10 and the volume furthest away from the heat exchange surface 10, is further away from the heat exchange surface 10. Therefore, after heat transfer fluid 2 has flowed into the inversion interface 15, it is the second volume of heat transfer fluid v2 that is present between the heat exchange surface 10 and the first volume of heat transfer fluid v1.

Specifically, the exchange of heat from the heat exchange surface 10 to the heat transfer fluid 2 in the vicinity of the heat exchange surface 10 increases the temperature of the heat transfer fluid 2 present in the first volume v1. Therefore, the inversion interface 15 makes it possible to replace the hot heat transfer fluid 2′ present in the first volume v1 and having a low capacity for heat extraction with the colder heat transfer fluid 2″ present in the second volume v2 in order to improve the exchange of heat between the heat transfer fluid 2 and the heat exchange surface 10.

The inversion of the two volumes of heat transfer fluid, i.e. the first volume v1 and the second volume v2, has the advantage of allowing the coldest heat transfer fluid 2 to be positioned in the vicinity of the heat exchange surface, this fluid being available for the entire time that the heat exchange surface 10 and the heat transfer fluid 2 are exchanging heat, by replacing a hot heat transfer fluid 2′ with a heat transfer fluid 2″ which is colder by comparison, the exchange by convection happening mainly in the vicinity of the heat exchange surface. Therefore, the thermal gradient between the heat exchange surface 10 and the heat transfer fluid 2 disposed in the vicinity of the heat exchange surface remains high, improving the extraction of heat.

Moreover, moving away the hot heat transfer fluid 2′ which is initially present in the first volume v1 and which thus has a low capacity for heat extraction also allows this heat transfer fluid to cool down in contact with a medium which is cooler than the heat exchange surface 10. It is then possible to envisage repeatedly and regularly inverting the heat transfer fluid 2 present in the first volume v1 and in the second volume v2 such that the extraction of heat as the heat transfer fluid 2 traverses the cooling fin in the first direction D1 is improved.

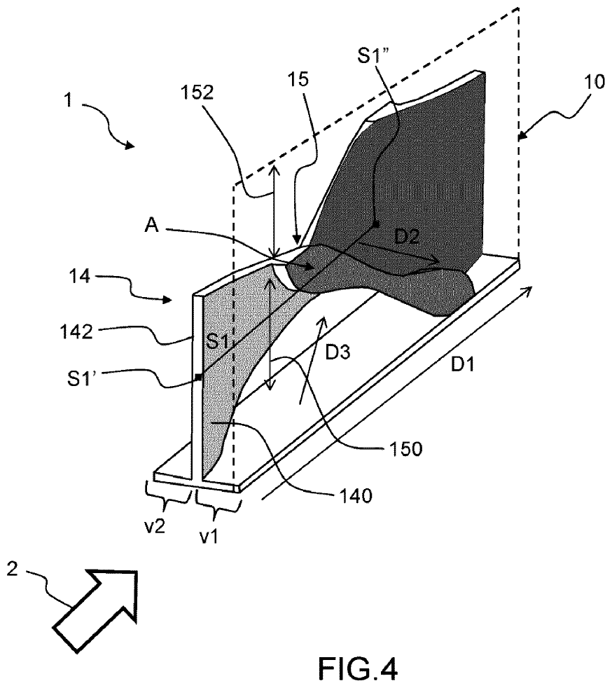

FIG. 4 shows an enlarged view of the fluid inversion interface 15 and the first wall 120 of the cooling fin 12. The inversion interface 15 thus makes it possible to invert the position of the heat transfer fluid 2 present in the first volume v1 and in the second volume v2 by simultaneously orienting the heat transfer fluid 2 in the second direction D2 and in the third direction D3. The inversion interface 15 for inverting the heat transfer fluid comprises a first stream inversion zone 150 connected to the first wall 120 and a second stream inversion zone 152 also connected to the first wall 120.

It is conceivable, in a configuration of the cooling fin 12 that also comprises the second wall 122, that the first inversion zone 150 and/or the second inversion zone 152 are connected solely to the second wall or that the first inversion zone 150 and/or the second inversion zone 152 are connected to the first wall 120 and to the second wall 122.

Thus, in the first inversion zone 150, the first guide surface 140 has a convex shape with respect to the heat exchange zone 10 and a concave shape with respect to the first segment S1. The second guide surface 142 also has a concave shape with respect to the first segment S1 and with respect to the heat exchange surface 10 in the second inversion zone 152.

In other words, the first guide surface 140 in the first inversion zone 150 has a concave shape between two boundaries S1′ and S1″ of the first segment S1 and the second guide surface 142 in the second inversion zone 152 has a concave shape between the two boundaries S1′ and S1″ of the first segment S1 that are obtained by the non-ruled, warped shape of the swirling guide 14.

As a result, the swirling guide 14 makes it possible to create two rectilinear corridors superimposed with and parallel to the heat exchange surface 10 and the inversion interface 15 makes it possible to invert the position of these two rectilinear corridors, i.e. the first volume v1 and the second volume v2, with respect to the heat exchange surface 10 without the heat transfer fluid present in one of the volumes, the first volume v1 or the second volume v2, being in contact with the heat transfer fluid present in the other volume, the first volume v1 or the second volume v2, in the manner of a redirecting baffle.

The inversion interface 15 thus has the advantage of making it possible to obtain an inversion in just one movement, the deflection of the heat transfer fluid in the first volume v1 and the deflection of the heat transfer fluid in the second fluid v2 happening simultaneously, and not successively along the heat exchange surface 10.

In other words, the inversion interface 15 makes it possible to invert the position of the first volume v1 and the second volume v2 at a single point A with respect to the heat exchange surface 10, and this limits the number of components or shapes required to invert the position of the heat transfer streams 2 in the cooling fin 12.

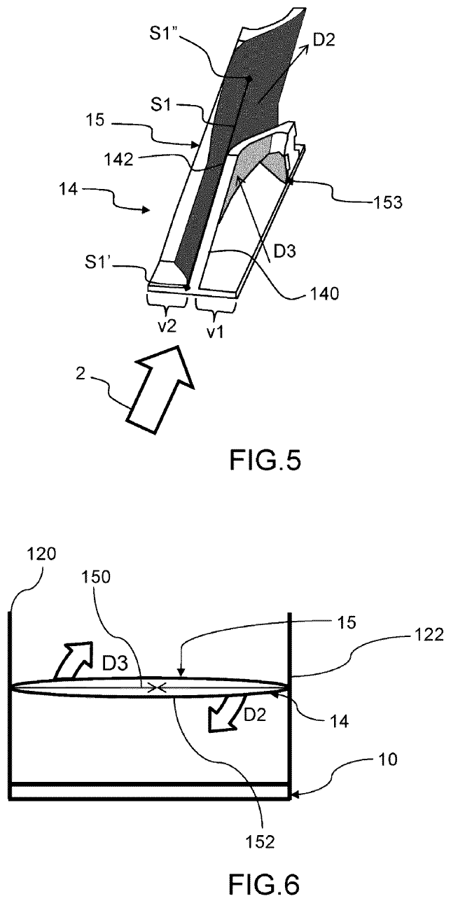

FIG. 5 shows an enlarged view of the inversion interface 15 at an angle from above.

As a result, as mentioned above, the inversion interface 15 makes it possible to invert the position of these two rectilinear corridors, i.e. the first volume v1 and the second volume v2, with respect to the heat exchange surface 10 without the heat transfer fluid present in one of the volumes, the first volume v1 or the second volume v2, being in contact with the heat transfer fluid present in the other volume, the first volume v1 or the second volume v2, in the manner of a redirecting baffle. This baffle makes it possible to direct the cool heat transfer fluid 2″ in the second direction D2 into the vicinity of the heat exchange surface 10 and the hot heat transfer fluid 2′ in the third direction D3 such that the latter is moved away from the heat exchange surface 10. In order to establish this redirection of the heat transfer fluid 2 in the second direction D2 or in the third direction D3, the fluid inversion interface 15 may comprise an orientation stop 153 for blocking the heat transfer fluid and directing the heat transfer fluid in the third direction D3 as shown in FIG. 5. Moreover, an orientation stop for directing the heat transfer fluid present in the second volume v2 in the second direction D2 is also conceivable. The orientation stop 153 thus makes it possible to further orient the heat transfer fluid 2 by additionally also incorporating the first guide surface 140 in the first inversion zone 150.

Moreover, several configurations are conceivable.

It is conceivable, as shown in FIG. 6, for the inversion interface 15 and the swirling guide 14 to be parallel with respect to the heat exchange surface 10. Therefore, the first wall 120 is connected to the first inversion zone 150, which is also connected to the second inversion zone 152. The second inversion zone 152 is also connected to the second wall 122.

In another architectural configuration, it is also conceivable for the fluid-swirling guide 14 and the inversion interface 15 to be connected to the heat exchange surface 10. Therefore, the first inversion zone 150 may be connected to the heat exchange surface 10 and to the second inversion zone 152.

This configuration has the advantage that the fluid-swirling guide 14 can also be thermally conductive. Therefore, the heat transfer fluid 2 in contact with the swirling guide 14 and the inversion interface 15 can also allow an exchange of heat with the heat transfer fluid 2.

In a configuration shown in FIG. 8, it is conceivable for the fluid-swirling guide 14 and the inversion interface 15 to be connected to the heat exchange surface 10 and to the walls 120 and 122 of the cooling fin. Therefore, the first inversion zone 150 may be connected to the heat exchange surface 10 while the second inversion zone 152 may be connected to the second wall 122. This configuration has the advantage of allowing a good conduction of heat in the swirling guide 14 while still allowing the swirling guide 14 to be properly fixed in the cooling fin. In a variant, it is conceivable for the first inversion zone 150 to be connected to the first wall 120 and at a small distance from the heat exchange surface 10. In another variant, the second inversion zone 152 may be connected to the heat exchange surface 10 and the first inversion zone 150 is connected to the first wall 120.

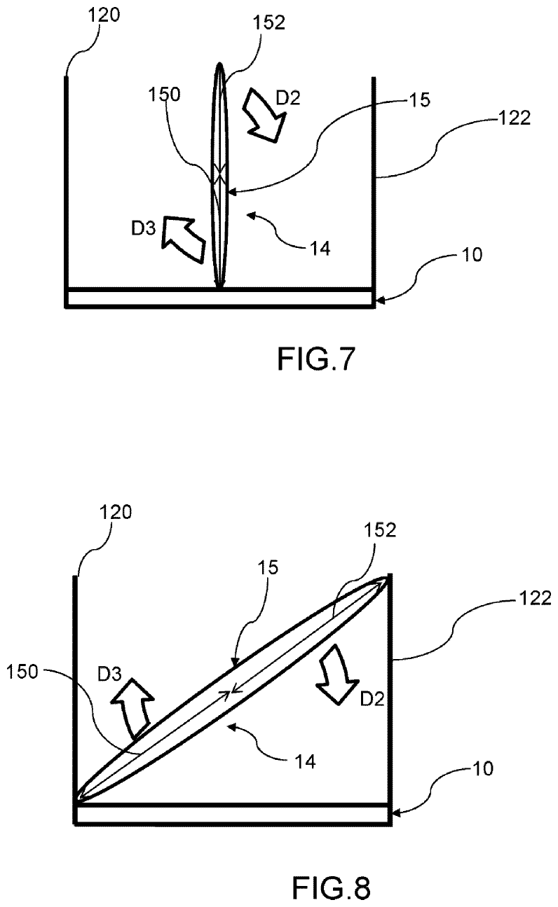

In another configuration shown in FIG. 7, it is also conceivable for the inversion interface 15 to comprise more than two inversion zones. By way of indicative example, the inversion interface 15 may comprise the first inversion zone 150, the second inversion zone 152 and a third inversion zone 152′ for directing the heat transfer fluid in a direction D2′ oriented toward the heat exchange surface 10. Moreover, the first inversion zone 150 may be present between the second inversion zone 152 and the third inversion zone 152′, allowing the cold heat transfer fluid 2″ to be distributed more evenly in the vicinity of the heat exchange surface 10.

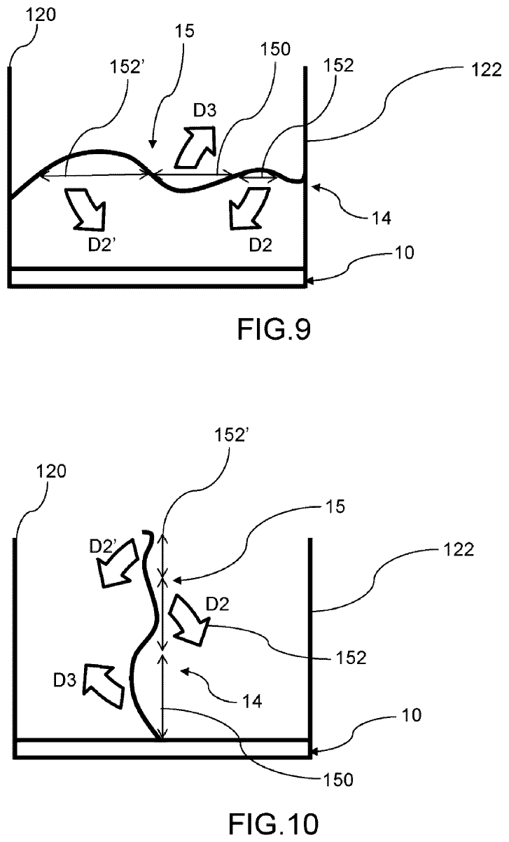

According to another configuration shown in FIG. 10, it is also conceivable to connect the inversion interface 15 from FIG. 9 directly to the heat exchange surface 10 so that the fluid-swirling guide 14 is thermally conductive. Moreover, in this configuration with the swirling guide 14 parallel to the walls of the cooling fin 12, it is conceivable for the second inversion zone 152 to be present between the first inversion zone 150 and the third inversion zone 152′. By contrast to the configuration in FIG. 9, the third inversion zone 152′ is disposed such that the direction D2′ intersects the third direction D3. Therefore, the heat transfer fluid 2 reoriented by the third inversion zone 152′ comes into contact with the hot heat transfer fluid 2′ reoriented by the first inversion zone 150 such that the hot heat transfer fluid 2′ is cooled down. As a result, there is an inversion of the heat transfer fluids via the first inversion zone 150 and the second inversion zone 152 and there is also a swirling of heat transfer fluid for cooling down the hot heat transfer fluid which is initially in the vicinity of the heat exchange surface 10 so that it is cooled down as efficiently as possible.

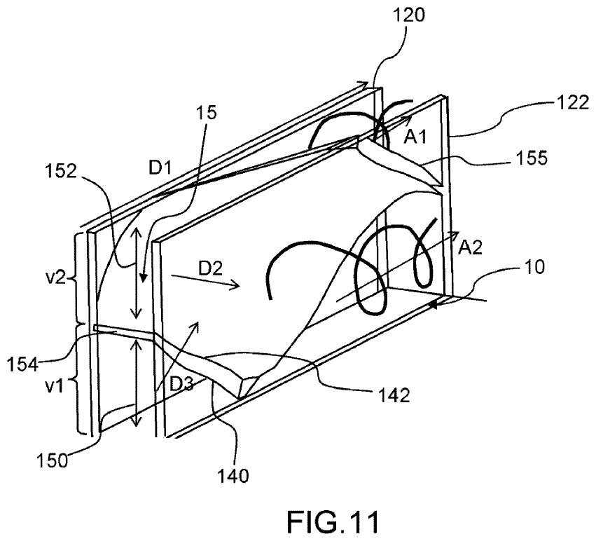

In addition, it is conceivable, as shown in FIG. 11, for the first inversion zone 150 to be able to induce a first rotation of the hot heat transfer fluid 2′ of the first volume v1 of heat transfer fluid about an axis of rotation A1 parallel to the first direction D1 and for the second inversion zone 152 to be able to induce a second rotation of the cold heat transfer fluid 2″ of the second volume v2 of heat transfer fluid 2 about an axis of rotation A2 parallel to the first direction D1. Therefore, establishing a rotation or a helical movement about the axis of rotation A2 has the advantage of improving the swirling of the heat transfer fluid in the vicinity of the heat exchange surface 10, allowing a uniform temperature to be obtained in the first volume v1. Moreover, this type of helical movement also has the advantage of lengthening the distance traveled by the heat transfer fluid 2 along the heat exchange surface 10 and thus of prolonging the time during which an exchange of heat by convection can take place.

The configuration in FIG. 11 shows a preferred configuration of a stream inversion between a stream which is further away from the heat exchange surface 10 and a stream which is close to the heat exchange surface, these streams then being inverted by the action of the inversion interface 15.

Moreover, in a configuration in which the first wall 120 and/or the second wall 122 is thermally conductive, establishing a rotation of the heat transfer fluid makes it possible to orient the heat transfer fluid into the vicinity of the heat exchange surface 10 and toward the first wall 120 and/or the second wall 122.

In one variant, the at least one swirling guide 14 may also comprise an additional guide extending perpendicularly to the first wall 120 and to the second wall 122. The additional guide then comprises a first additional guide surface facing the first wall 120 and/or a second additional guide surface facing the second wall 122. The first additional guide surface and the second additional guide surface can then have a convex shape with respect to the first segment S1 substantially parallel to the first direction D1. The additional guide thus has the shape of a protuberance of material extending from the at least one swirling guide 14 toward the first wall 120 or the second wall 122 and thus allows some of the heat transfer fluid 2 present in the first volume v1 or in the second volume v2 to be directed toward the first wall 120 or toward the second wall 122, respectively, in order to increase the amount of contact and the exchange of heat between the heat transfer fluid 2 and the first wall 120 and/or the second wall 122. In a variant, the first additional guide surface and the second additional guide surface can then have a convex shape with respect to the first segment S1.

In order to generate this rotational movement of the heat transfer fluid 2 in the first volume v1 and in the second volume v2, the first guide surface 140 in the first inversion zone 150 and the second guide surface 142 in the second inversion zone 152 may be defined according to the following mathematical equation:

$$D = {f}_{1} ( X ) \cdot sin ( {f}_{2} ( X ) )$$

Where D represents the movement of the heat transfer fluid 2 with respect to the first direction D1 between an entrance 154 of the inversion interface 15 and an exit 155 of the inversion interface 15 in the first direction D1, X represents a position of the heat transfer fluid 2 along the first direction D1 between the entrance 154 of the inversion interface 15 and the exit 155 of the inversion interface 15, X being arbitrarily defined as 0 at the entrance 154 to the inversion interface 15, and fₓ represent any mathematical functions.

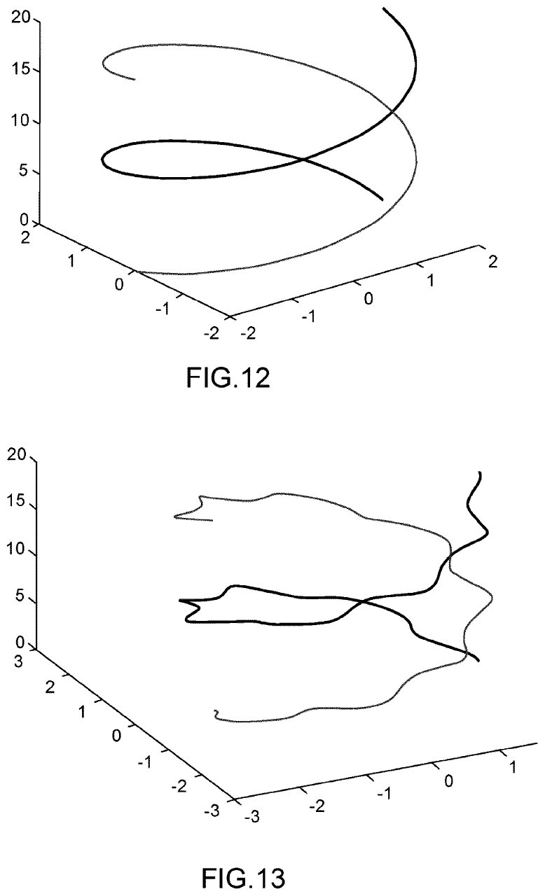

It is therefore possible to obtain two rotational or helical movements about the axes of rotation A1 and A2, as shown in FIG. 12.

In addition, it is also conceivable to add an oscillation curve to the helical movement of the heat transfer fluid of the first and second volumes v1 and v2.

For example, returning to the equation above, it is possible to obtain a carrier as shown in FIG. 12 according to the following formula:

$$Carrier = Amplitude \cdot sin ( 2 \cdot π \cdot Frequency \cdot t )$$

Where t represents the time and Amplitude represents the amplitude of the carrier and thus of the helical movement.

More specifically, it is possible to define the movement of a first heat transfer fluid, for example the heat transfer fluid of the first volume v1 redirected toward the second volume v2, according to the following equations:

$$x = α \cdot cos ( t )$$

$$y = β \cdot sin ( t )$$

$$z = γ \cdot t$$

Where αβγ represent real coefficients, and x and y represent Cartesian coordinates of the first heat transfer fluid in a plane perpendicular to the first direction D1 of the heat transfer fluid in the cooling fin 12 and z represents the Cartesian coordinate of the first heat transfer fluid parallel to the first direction D1.

It is also possible to define the movement of a second heat transfer fluid, for example the heat transfer fluid of the second volume v2 redirected toward the first volume v2, according to the following equations:

$${x}^{′} = α \cdot cos ( t + π )$$

$${y}^{′} = β \cdot sin ( t + π )$$

$${z}^{′} = γ \cdot t$$

With an offset of π between the position of the first heat transfer fluid and the second heat transfer fluid in the plane perpendicular to the first direction D1 and where x′ and y′ represent Cartesian coordinates of the second heat transfer fluid in a plane perpendicular to the first direction D1 of the heat transfer fluid in the cooling fin 12 and z′ represents the Cartesian coordinate of the second heat transfer fluid parallel to the first direction D1.

And, by adding a frequency over-modulation, it is possible to obtain an oscillating helical movement as shown in FIG. 13. By way of indicative example, this over-modulation can be obtained by multiplying the preceding formula with a modulator:

$$ModulatedCarrier = [ Amptitude + {amplitude}_{modulation} \cdot sin ( 2 \cdot π \cdot {frequency}_{modulation} \cdot t + φ ) ] \times sin ( 2 \cdot π \cdot Frequency \cdot t + φ )$$

amplitude_{modulation} represents the amplitude of the modulation applied to the carrier, i.e. the variation in amplitude in the helicoid, and frequency_{modulation} represents the frequency of the modulation applied to the helicoid.

Therefore, the movement of the first heat transfer fluid can be defined according to the following equations:

$$x = ( A + a * cos ( 2 * pi * f * t + φ ) ) . * cos ( 2 * p i * F * t + φ ) ;$$

$$y = ( A + a * sin ( 2 * pi * f * t + φ ) ) . * sin ( 2 * p i * F * t + φ ) ;$$

$$z = γ * t ;$$

Where A represents the amplitude of the helical movement of the first heat transfer fluid as shown in FIG. 12 and a represents the amplitude of the modulation applied to the carrier, f represents the frequency of the modulation applied to the helicoid and F represents the frequency of the carrier, i.e. of the helical movement of the first heat transfer fluid as shown in FIG. 12.

The movement of the second heat transfer fluid can also be defined according to the following equations:

$${x}^{′} = ( A + a * cos ( 2 * pi * f * t + φ + π ) ) . * cos ( 2 * p i * F * t + φ + π ) ;$$

$${y}^{′} = ( A + a * sin ( 2 * pi * f * t + φ + π ) ) . * sin ( 2 * p i * F * t + φ + π ) ;$$

$${z}^{′} = γ * t ;$$

With an offset of π between the position of the first heat transfer fluid and the second heat transfer fluid in the plane perpendicular to the first direction D1.

This over-modulation has the advantage of making it possible to obtain an oscillation of the heat transfer fluid in the vicinity of the heat exchange surface, i.e. a lengthening of the distance traveled by the heat transfer fluid 2 along the heat exchange surface and thus a better exchange with the heat exchange surface 10. This helical movement about an axis of rotation accompanied by an oscillation about an axis radial to the axis of rotation also has the advantage of making better use of the available volume in the cooling fin for the swirling, thereby allowing an improvement in the temperature uniformity.

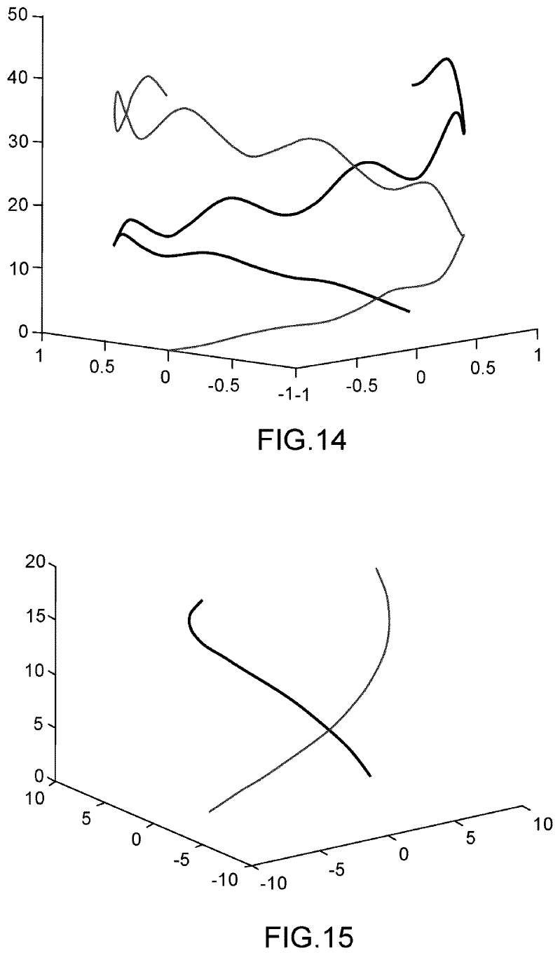

Moreover, the oscillation is in the plane of the helix. It is also conceivable to add an additional oscillation in the direction of flow of the heat transfer fluid, parallel to the first direction D1 as shown in FIG. 14, by combining a modulation in the plane of the first direction D1 with the aforementioned formula for obtaining the carrier.

Therefore, the movement of the first heat transfer fluid can be defined according to the following equations:

$$x = cos ( 2 * pi * F * t + φ ) ;$$

$$y = sin ( 2 * pi * F * t + φ ) ;$$

$$z = ( A + a * cos ( 2 * pi * f * t + φ + π ) ) * ( γ * t ) ;$$

The movement of the second heat transfer fluid can also be defined according to the following equations:

$${x}^{′} = cos ( 2 * p i * F * t + φ + π ) ;$$

$${y}^{′} = sin ( 2 * p i * F * t + φ + π ) ;$$

$${z}^{′} = ( A + a * sin ( 2 * pi * f * t + φ + π ) ) . * ( 20 * t ) ;$$

This affords a helical movement coupled with a sinusoidal movement.

In a variant, it is also conceivable for the inversion interface 15 to generate a movement of the polynomial type. The first guide surface 140 in the first inversion zone 150 and the second guide surface 142 in the second inversion zone 152 may be defined according to the following mathematical equation:

$$D = {\sum }_{0}^{n} {α}_{n} \cdot {X}^{n}$$

where D represents the movement of the heat transfer fluid with respect to the first direction D1 between the entrance 154 of the inversion interface 15 and the exit 155 of the inversion interface 15 in the first direction D1, X represents a position of the heat transfer fluid 2 along the first direction D1 between the entrance 154 of the inversion interface 15 and the exit 155 of the inversion interface 15, X being arbitrarily defined as 0 at the entrance to the inversion interface 15, and an represents a parameter of the real coefficient type.

It is therefore conceivable to induce a hybrid movement in relation to the rotational movement induced in the first heat transfer fluid and in the second heat transfer fluid as indicated in FIGS. 12 to 14.

Thus, as shown in FIG. 15, the movement of the first heat transfer fluid can be defined according to the following equations:

$$x = A * cos ( π * t ) ;$$

$$y = A * sin ( π * t ) ;$$

$$z = H * t ;$$

While the movement of the second heat transfer fluid can be defined according to the following equations:

$${x}^{′} = A * cos ( π * t + π ) ;$$

$${y}^{′} = A * sin ( π * t + π ) ;$$

$${z}^{′} = H * t ;$$

With an offset of π in the plane perpendicular to the first direction D1.

This movement can then be likened to an ADN architecture.

According to one aspect of the invention, the heat transfer fluid 2 may advantageously be air. However, any heat transfer fluid that has a good capacity for heat extraction can be envisaged as heat transfer fluid 2 traversing the cooling fin 12.

The object of the present invention is therefore to provide a shape of a cooling fin 12 for swirling the heat transfer fluid 2 toward the heat transfer fluid for which the exchange of heat is to take place.

The aim of this swirling is to allow the heat transfer fluid entering the exchanger in a zone remote from the heat exchange surface 10 to come into a zone close to this heat exchange surface 10 at any point of the exchanger in the flow direction of said heat transfer fluid.

This same swirling oppositely makes the heat transfer fluid entering the exchanger in a zone close to the heat exchange surface flow into a zone remote from this same heat exchange surface along the thermal surface in the direction of the flow stream of this fluid.

This concept of swirling the inflowing fluid makes it possible to vary the thermal gradient between the fluid entering the exchanger and the conductive portions used for said exchange.

The aim of the shape is to allow regeneration of a heat transfer fluid 2, such as air, that has not been in contact with the heat exchange surface 10 at the entrance of the exchanger in the first direction D1 so that it can be further away therefrom along the first direction D1 in said exchanger as it flows through the heat exchanger.

The shape defined by a double guide curvature allows effective swirling while still limiting the pressure drops that can be induced by excessively abrupt shapes.

The aim is to optimize the exchanges of heat by increasing the thermal gradient along the stream of fluid in the heat exchanger, in that the temperature of the fluid in contact with the exchange surface varies along the stream, reducing its gradient with the second thermal element; having a shape for swirling the stream brings fluid that has not exchanged heat, or has exchanged only a little heat, with the heat exchange surface toward the heat exchange surface in order to increase the temperature gradient, and thus the effectiveness of the heat exchange.

The cooling fin 12 may be continuous or intermittent in places, have communication orifices and/or projecting shapes that can serve to modify the flow of the fluid and establish swirling or even an inversion of the position of the heat transfer fluid with respect to the heat exchange surface 10.

This type of fluid-swirling guide 14 and fluid inversion interface 15 is advantageously produced by a metal 3D printing additive manufacturing process. In a variant, any 3D printing additive manufacturing process is conceivable.

1. A cooling device having a heat exchange surface configured to allow an exchange of heat with a heat transfer fluid along the heat exchange surface in a first direction, the exchange of heat being brought about by convection between the heat exchange surface and the heat transfer fluid, the cooling device comprising at least one cooling fin, the heat exchange surface being configured to receive, by conduction, heat that is to be discharged by the cooling fin, the cooling fin comprising at least one fixed fluid-swirling guide spaced apart from the heat exchange surface, the at least one fluid-swirling guide having a warped surface, the at least one fluid-swirling guide being disposed so that the heat transfer fluid is redirected in a second direction (D2) intersecting the first direction (D1).

2. The cooling device as claimed in claim 1, wherein the second direction (D2) is oriented toward the heat exchange surface, the second direction (D2) having a component substantially perpendicular to the heat exchange surface.

3. The cooling device as claimed in claim 2, wherein the at least one swirling guide is disposed so that the heat transfer fluid is redirected in a third direction (D3) intersecting the first direction (D1) and the second direction (D2), the third direction (D3) having the same origin as the second direction (D2) in a first plane (P1) perpendicular to the heat exchange surface, the third direction (D3) having a component substantially perpendicular to the heat exchange surface that opposes the component substantially perpendicular to the heat exchange surface of the second direction (D2) in the first plane (P1).

4. The cooling device as claimed in claim 3, wherein the cooling fin comprises:
a first wall extending in a second plane (P2) substantially parallel to the first direction (D1) and parallel to the first plane (P1), the first wall being configured to receive, by conduction, heat that is to be discharged by the cooling fin, the at least one swirling guide being connected to the first wall via a first fixing support.

5. The cooling device as claimed in claim 4, wherein the cooling fin comprises:
a second wall extending in a third plane (P3) parallel to the first plane (P1) and separate from the second plane (P2), the swirling guide being connected to the second wall via a second fixing support.

6. The cooling device as claimed in claim 5, wherein the second plane (P2) is parallel to the first plane (P1) and/or the third plane (P3) is parallel to the first plane (P1).

7. The cooling device as claimed in claim 5, wherein the heat transfer fluid present between the first wall and the second wall comprises a first volume (v1) of heat transfer fluid disposed between the heat exchange surface and a first guide surface of the at least one swirling guide for swirling the heat transfer fluid and a second volume (v2) of heat transfer fluid in contact with a second guide surface of the at least one fluid-swirling guide, the first guide surface having a concave shape and the second guide surface having a concave shape with respect to a first segment (S1) substantially coinciding with the at least one fluid-swirling guide and parallel to the first direction (D1).

8. The cooling device as claimed in claim 7, wherein the at least one fluid-swirling guide comprises an inversion interface for inverting the heat transfer fluid and configured to redirect the heat transfer fluid present in the second volume (v2) of heat transfer fluid toward the first volume (v1) of heat transfer fluid.

9. The cooling device as claimed in claim 8, wherein the inversion interface for inverting the heat transfer fluid is configured to redirect the heat transfer fluid present in the first volume (v1) of heat transfer fluid toward the second volume (v2) of heat transfer fluid.

10. The cooling device as claimed in claim 8, wherein the inversion interface for inverting the heat transfer fluid comprises a first stream inversion zone connected to the first wall and/or the second wall and a second stream inversion zone connected to the first wall and/or the second wall, the first guide surface in the first inversion zone having a concave shape with respect to the heat exchange zone and the second guide surface in the second inversion zone having a convex shape with respect to the heat exchange surface.

11. The cooling device as claimed in claim 10, wherein the first guide surface in the first inversion zone has a concave shape between two boundaries of the first segment (S1) and the second guide surface in the second inversion zone has a concave shape between the two boundaries of the first segment (S1).

12. The cooling device as claimed in claim 10, wherein the first inversion zone is capable of inducing a first rotation of the heat transfer fluid of the first volume (v1) of heat transfer fluid and wherein the second inversion zone is capable of inducing a second rotation of the heat transfer fluid of the second volume (v2) of heat transfer fluid (2) about an axis of rotation parallel to the first direction (D1).

13. The cooling device as claimed in claim 5, wherein the at least one swirling guide comprises an additional guide extending perpendicularly in relation to the first wall and to the second wall, the additional guide comprising a first additional guide surface facing the first wall and a second additional guide surface facing the second wall, the first additional guide surface and the second additional guide surface having a convex shape along a second segment substantially coinciding with the additional guide and parallel to the first direction (D1).

14. The cooling device as claimed in claim 10, wherein the first guide surface in the first inversion zone and the second guide surface in the second inversion zone are defined according to the following mathematical equation:
$$D = {f}_{1} ( X ) \cdot sin ( {f}_{2} ( X ) )$$
where D represents the movement of the heat transfer fluid with respect to the first direction (D1) between an entrance of the inversion interface and an exit of the inversion interface in the first direction (D1), X represents a position of the heat transfer fluid along the first direction (D1) between the entrance of the inversion interface and the exit of the inversion interface, X being arbitrarily defined as 0 at the entrance to the inversion interface, and fₓ represent any mathematical functions.

15. The cooling device as claimed in claim 10, wherein the first guide surface in the first inversion zone and the second guide surface in the second inversion zone are defined according to the following mathematical equation:
$$D = {\sum }_{0}^{n} {α}_{n} \cdot {X}^{n}$$
where D represents the movement of the heat transfer fluid with respect to the first direction (D1) between an entrance of the inversion interface and an exit of the inversion interface in the first direction (D1), X represents a position of the heat transfer fluid along the first direction (D1) between the entrance of the inversion interface and the exit of the inversion interface, X being arbitrarily defined as 0 at the entrance to the inversion interface, and αₙ represents a parameter of the real coefficient type.
